(19) United States
(12) Patent Application Publication
(10) Pub. No.: US 2025/0158588 A1
(43) Pub. Date: May 15, 2025

(54) NOISE FILTER AND NOISE REMOVAL METHOD

(71) Applicant: Mitsubishi Electric Corporation, Tokyo (JP)

(72) Inventors: Kaito HAGIWARA, Tokyo (JP); Kyota OTSUKA, Tokyo (JP); Kenji HIROSE, Tokyo (JP)

(73) Assignee: Mitsubishi Electric Corporation, Tokyo (JP)

(21) Appl. No.: 19/020,972

(22) Filed: Jan. 14, 2025

Related U.S. Application Data
(63) Continuation of application No. PCT/JP2022/034191, filed on Sep. 13, 2022.

(51) Int. Cl. H03H 7/01

(52) U.S. Cl. CPC H03H 7/0153

(57) ABSTRACT

If a fuse is applied as an overcurrent protection circuit to block impulse noises and thus a transmission line is electrically disconnected, the line will remain disconnected until a new fuse is installed, making it difficult to continuously operate a load. The noise filter according to the present disclosure includes a controller that turns off a switching element when a time equivalent to a time from detecting a first impulse noise to detecting a second impulse noise has elapsed after detecting the second impulse noise, so that the impulse noises are prevented from entering the load without hindering the continuous operation of the load.

### CROSS REFERENCE TO RELATED APPLICATIONS

This application is a Continuation of PCT International Application No. PCT/JP2022/034191 filed on Sep. 13, 2022, all of which is hereby expressly incorporated by reference into the present application.

### TECHNICAL FIELD

The present disclosure relates to a filter for periodic impulse noises.

### BACKGROUND TECHNOLOGY

As a conventional technology, for example, Patent Document 1 describes a power source circuit that performs a protective operation when impulse noises generated by a surge voltage occurs or an unsuitable power is supplied. In a power source circuit of Patent Document 1, for example, a low-pass filter with a coil and a capacitor is inserted between an AC power transmission line, which is a monitoring target of an overvoltage detection circuit, and the overvoltage detection circuit. This low-pass filter removes the impulse noises. Furthermore, this power source circuit includes an overcurrent protection circuit that electrically disconnects the transmission line when the overvoltage detection circuit detects an overvoltage in case an unsuitable power is supplied. The overcurrent protection circuit includes a fuse that melts down due to the overcurrent flowing through the transmission line.

### PRIOR ART DOCUMENTS

### Patent Documents

[Patent Document 1] Unexamined Japanese Patent Application Publication No. 2012-182956

### SUMMARY OF THE INVENTION

### Problems to be Solved by the Invention

In the power source circuit described in Patent Document 1, the impulse noises are removed by a low-pass filter including a coil and a capacitor. However, a capacitor cannot respond to rapid voltage changes, so that there is a possibility that some impulse noises may enter a load provided in the subsequent stage of the filter, and there is also a possibility that a core of the coil may become magnetically saturated, resulting in a loss of countermeasure effectiveness. In addition, if a fuse is applied as an overcurrent protection circuit to block the impulse noises that cannot be completely removed and thus the transmission line is electrically disconnected, the line will remain disconnected until a new fuse is installed, making it difficult to continuously operate the load.

### Means for Solving the Problems

A noise filter according to the present disclosure includes a switching element that is provided on a power line electrically connecting a power source and a load and switches the electrical connection and disconnection between the power source and the load by an on/off operation; a sensor that detects periodic impulse noises applied to the power line; and a controller that turns off the switching element when a time equivalent to a time from detecting a first impulse noise to detecting a second impulse noise has elapsed from detecting the second impulse noise.

### Effects of the Invention

The noise filter according to the present disclosure includes the controller that turns off the switching element when a time equivalent to a time from detecting the first impulse noise to detecting the second impulse noise has elapsed after detecting the second impulse noise, and thus disconnects the power source and the circuit in response to an arrival of the impulse noises without disconnecting the power source and the load by a fuse meltdown, so that the impulse noises are prevented from entering the load without hindering the continuous operation of the load.

### BRIEF DESCRIPTION OF THE DRAWINGS

FIG. 1 is a configuration diagram of a noise filter according to Embodiment 1.

FIG. 2 is a schematic diagram showing periodicity of impulse noises.

FIG. 3 is timing chart showing voltage changes on a power line and a load before application of the noise filter according to Embodiment 1.

FIG. 4 is a timing chart showing operation of components of the noise filter and the voltage changes on the power line and the load after the application of the noise filter according to Embodiment 1.

FIG. 5 is a flowchart showing operation of a controller according to Embodiment 1.

FIG. 6 is a state transition diagram of the controller according to Embodiment 1.

FIG. 7 is a configuration diagram of a noise filter in a modified example of Embodiment 1.

FIG. 8 is a schematic diagram showing the operation of the components of the noise filter, the voltage changes on the power line and the load, and the relationship between an off time of a switching element and the voltage between wires of the power source after the application of the noise filter in the modified example of Embodiment 1.

FIG. 9 is a configuration diagram of a noise filter according to Embodiment 2.

### EMBODIMENTS FOR IMPLEMENTING THE INVENTION

### Embodiment 1

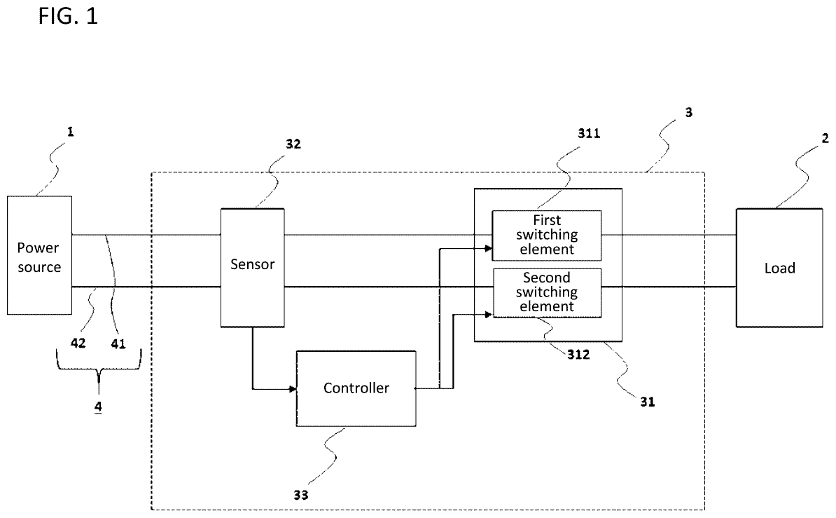

FIG. 1 is a configuration diagram of a noise filter 3 according to Embodiment 1. In Embodiment 1, a case in which the noise filter 3 is applied to a single-phase power line 4 will be described. As shown in FIG. 1, the noise filter 3 is provided between a power source 1 and a load 2. The power source 1 supplies power to the load 2. The power is supplied from the power source 1 to the load 2 via the power line 4, and the load 2 is driven by the supplied power. The load 2 includes one or more circuit elements. The power line 4 electrically connects the power source 1 and the load 2. The power line 4 consists of two wires, a first power source wire 41 and a second power source wire 42. When it is not necessary to separately describe the first power source wire 41 and the second power source wire 42, they will be simply referred to as the power line 4 from here on. In Embodiment 1, a case in which the power line 4 acts as a propagation path of impulse noises will be described.

The noise filter 3 includes a switching element 31, a sensor 32, and a controller 33, as shown in FIG. 1. The noise filter 3 is provided on the power line 4 to protect the load 2 from impulse noises.

The switching element 31 is provided on the power line 4 at a position closer to the power source 1 than the load 2. The switching element 31 consists of two switching elements, a first switching element 311 and a second switching element 312. The first switching element 311 is provided on the first power source wire 41. The second switching element 312 is provided on the second power source wire 42. For description of a case in which the first switching element 311 and the second switching element 312 perform the same operation, they will be referred to as the switching element 31 from here on.

Note that when only the first switching element 311 is operated and the second switching element 312 is not operated, there is a possibility that impulse noises will propagate through the second power source wire 42. Therefore, in order to prevent the propagation of impulse noises, in the present embodiment, the first switching element 311 and the second switching element 312 are operated simultaneously.

The switching element 31 switches electrical connection and disconnection between the power source 1 and the load 2 by an on/off operation. The switching element 31 electrically connects the power source 1 and the load 2 when in an on state, and electrically disconnects the power source 1 and the load 2 when in an off state. The switching element 31 is controlled by the controller 33 to perform the on/off operation, details of which will be described later. The switching element 31 is, for example, a switching diode. The switching element 31 is not limited to being provided separately for the noise filter 3, but may be substituted by a switching element provided in a circuit of a switching power source of a DC-DC converter, etc.

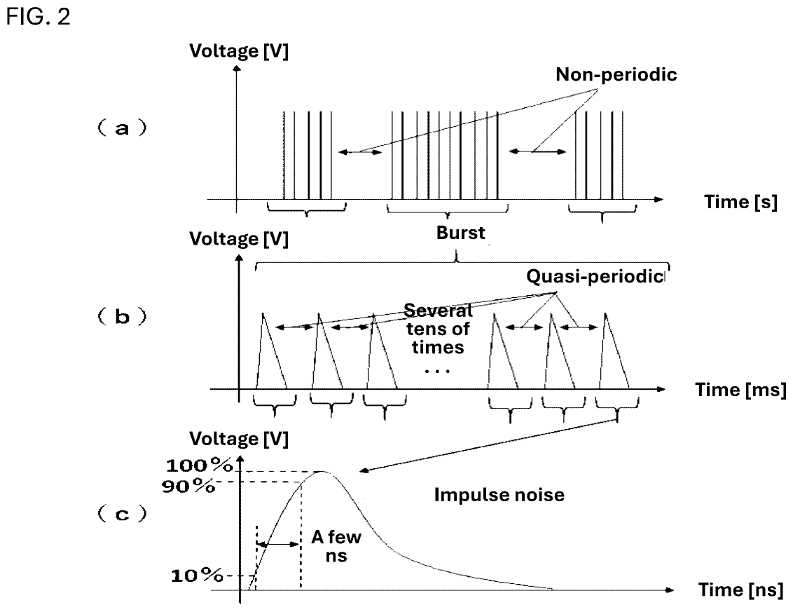

The sensor 32 is provided at a position closer to the power source 1 than the switching element 31 on the power line 4. The sensor 32 is, for example, a voltage sensor that measures a voltage applied to the power line 4. When a measured value of the voltage is equal to or greater than a predetermined value, the sensor 32 detects it as impulse noises. The impulse noises handled by the present embodiment will be described with reference to FIG. 2. FIG. 2 is a schematic diagram showing periodicity of the impulse noises. FIG. 2(a) is a schematic diagram showing non-periodicity of bursts. The burst refers to a bundle of several tens of impulse noises. As shown in FIG. 2(a), the bursts arrive non-periodically.

FIG. 2(b) is a schematic diagram showing the periodicity of a plurality of impulse noises included in a burst. As shown in FIG. 2(b), the plurality of impulse noises included in a single burst arrive periodically to some extent. In Embodiment 1, such impulse noises are referred to as periodic impulse noises. To be specific, the periodic impulse noises refer to impulse noises in which the time difference between the arrival of the first and second impulse noise and the time difference between the arrival of the second and third impulse noises are almost equal. In other words, the time difference between the arrivals of impulse noises included in a burst are approximately equal.

FIG. 2(c) is a schematic diagram showing a voltage waveform of a single impulse noise. As shown in FIG. 2(c), the impulse noises refer to electrical noises that are generated outside the load 2, propagate through the power line 4, and, when the maximum voltage is assumed to be 100%, has a voltage waveform that rises from 10% to 90% of the maximum in a few nanoseconds. The impulse noises are detected by the sensor 32 during this rise time of a few nanoseconds, for example.

Note that the sensor 32 is not limited to a voltage sensor, but may be a current sensor, an electric field sensor, or a magnetic field sensor. When the sensor 32 detects an impulse noise, it sends a detection result to the controller 33. The sensor 32 sends, as the detection result, for example, a sensor signal to the controller 33.

As shown in FIG. 1, the controller 33 controls the on/off operation of the switching element 31. The controller 33 is electrically connected to the switching element 31 and the sensor 32. The controller 33 is, for example, a circuit board or a device including a CPU and a memory. In this case, the controller 33 is operated by the CPU reading and executing a program stored in the memory. The controller 33 outputs a signal, such as a gate signal, to control the on/off operation of the switching element 31. The gate signal may be either a digital or an analog signal, and it is selected according to a driving method of the switching element 31. Here, a case in which the gate signal is a digital signal will be described.

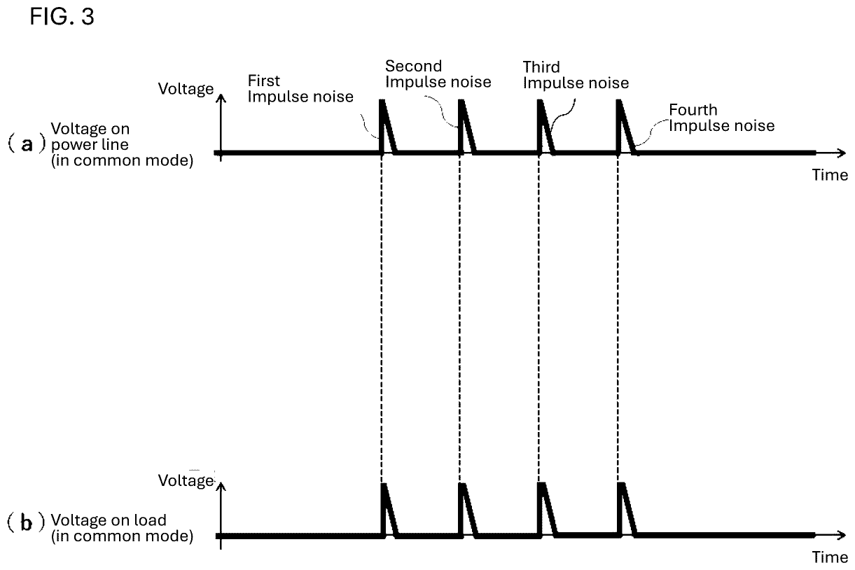

Next, the operation of the noise filter 3 will be described. FIG. 3 is a timing chart showing voltage changes on the power line 4 and the load 2 before the application of the noise filter 3 according to Embodiment 1. FIG. 3(a) shows the voltage change on the power line 4 before the application of the noise filter according to Embodiment 1. When the periodic impulse noises propagate on the power line 4, the voltage of the impulse noises is superimposed on a common mode voltage of the power line 4, as shown in FIG. 3(a). Here, the common mode refers to the case in which the reference voltages of the first power source wire 41 and the second power source wire 42 are grounded. In Embodiment 1, a case in which the waveforms of the voltages applied to the first power source wire 41 and the second power source wire 42 are in phase with each other will be described. FIG. 3(a) shows that four of the periodic impulse noises arrive at the power line 4. These impulse noises are referred to as a first impulse noise, a second impulse noise, a third impulse noise, and a fourth impulse noise in order of arrival. The second impulse noise is detected by the sensor 32 following the first impulse noise. Similarly, the third impulse noise is detected by the sensor 32 following the second impulse noise, and the fourth impulse noise is detected by the sensor 32 following the third impulse noise.

FIG. 3(b) shows the voltage change on the load 2 before the application of the noise filter according to Embodiment 1. FIG. 3(b) illustrates an example in which the voltages of the impulse noises are superimposed on the common mode voltage of the load 2. As can be seen from FIG. 3(b), when the noise filter 3 is not applied, the impulse noises will propagate to the load 2.

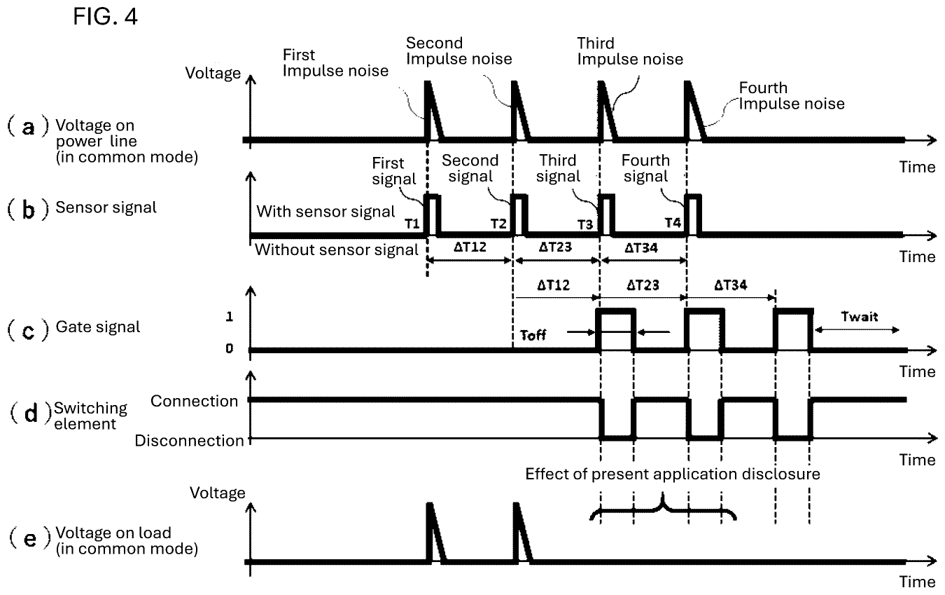

FIG. 4 is a timing chart showing the operation of the components of the noise filter 3 and the voltage changes on the power line 4 and the load 2 after the application of the noise filter 3 according to Embodiment 1. FIG. 4(a) shows the voltage change on the power line 4 after the application of the noise filter 3 according to Embodiment 1. When the periodic impulse noises propagate on the power line 4, the voltages of the impulse noises are superimposed on the common mode voltage of the power line 4, as shown in FIG. 4(a). FIG. 4(a) also shows, as in FIG. 3(a), that the first to fourth impulse noises arrive at the power line 4.

FIG. 4(b) shows the operation of the sensor 32 after the application of the noise filter 3 according to Embodiment 1. In FIG. 4(b), it is illustrated that when the sensor 32 detects an impulse noise, it sends a sensor signal to the controller 33. When the sensor 32 detects the first impulse noise, it sends a first signal, as a corresponding sensor signal, to the controller 33. Similarly, when the sensor 32 detects the second, third, and fourth impulse noises, it sends a second, third, and fourth signals as sensor signals to the controller 33.

FIG. 4(c) shows the operation of the controller 33 after the application of the noise filter 3 according to Embodiment 1. In FIG. 4(c), it is illustrated that the controller 33 sends the gate signals to the switching element 31 in accordance with the times at which the impulse noises arrive. The controller 33 calculates the time differences ΔT12, ΔT23, and ΔT34, which are the differences between the times when each impulse noise arrives, based on the times when it receives the sensor signals. The time difference ΔT12 is the difference in time between the arrivals of the first and second impulse noises, corresponding to the time from detecting the first impulse noise to detecting the second impulse noise. Similarly, the time difference ΔT23 is the difference in time between the arrivals of the second and third impulse noises, and the time difference ΔT34 is the difference in time between the arrivals of the third and fourth impulse noises. When the time difference ΔT12 has elapsed from the time of arrival of the second impulse noise, the controller 33 sends a gate signal=1 to the switching element 31. When the gate signal=1 is received, the switching element 31 turns to the off state. When the switching element 31 turns to the off state, the power line 4 is electrically disconnected at the location where the switching element 31 is provided, so that the load 2 is electrically disconnected from the power source 1.

FIG. 4(d) shows the operation of the switching element 31 after the application of the noise filter 3 according to Embodiment 1. In FIG. 4(d), it is illustrated that the switching element 31 performs electrical connection and disconnection between the power source 1 and the load 2 in accordance with the gate signals sent from the controller 33 to the switching element 31 as shown in FIG. 4(c).

After the time difference ΔT12 has elapsed, when an off time Toff has further elapsed, the controller 33 sends a gate signal=0 to the switching element 31. The off time Toff refers to the time during which the load 2 is electrically disconnected from the power source 1. The length of the off time Toff, for example, is several hundred nanoseconds. When the gate signal=0 is received, the switching element 31 turns on. When the switching element 31 turns to the on state, the power line 4 is electrically connected at the location where the switching element 31 is provided, so that the load 2 is electrically connected to the power source 1.

The controller 33 operates in the same manner as when the time difference ΔT12 has elapsed from the time at which the second impulse noise arrives, both after the time difference ΔT23 has elapsed from the time at which the third impulse noise arrives and after the time difference ΔT34 has elapsed from the time at which the fourth impulse noise arrives. In this way, because the controller 33 performs the operation for each of the successive impulse noises, the noise filter 3 can remove all the successive impulse noises without fail starting from the third one.

After the time difference ΔT34 has elapsed from the time at which the fourth impulse noise is to arrive, further, when a sensor signal is not received from the sensor 32 during the elapse of the off time Toff, the controller 33 further waits for a waiting time Twait after the elapse of the off time Toff. When no sensor signal is received from the sensor 32 during the waiting time Twait, the controller 33 determines that the burst has ended and returns to a state of waiting for a sensor signal from the sensor 32. When a sensor signal is received from the sensor 32 during the waiting time Twait, the controller 33 repeats the operation shown in FIG. 4(c). The waiting time Twait should be sufficiently long compared to the off time Toff, for example, a few seconds.

FIG. 4(e) shows the voltage change on the load 2 after the application of the noise filter 3 according to Embodiment 1. FIG. 4(e) illustrates that the voltages of the third and fourth impulse noises are not superimposed on the common mode voltage applied to the load 2. As described above, the controller 33 controls the on/off operation of the switching element 31 in accordance with the times at which the impulse noises arrive. By electrically disconnecting the load 2 from the power source 1 in accordance with the times when the impulse noises arrive, the switching element 31 can protect the load 2 from the impulse noises.

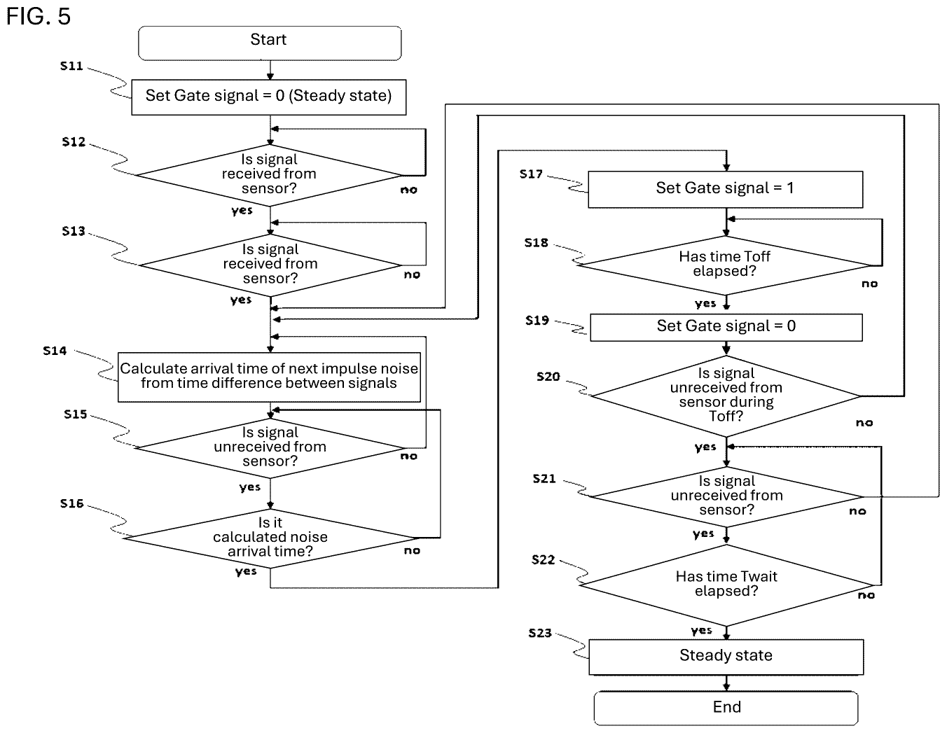

Next, the operation of the controller 33 for protecting the load 2 from the impulse noises will be described in detail with reference to FIG. 5. FIG. 5 is a flowchart showing the operation of the controller 33. When the controller 33 enters a steady state, it starts operating. The steady state refers to a state in which the controller 33 waits for the reception of the first signal from the sensor 32. This includes a case where the controller 33 enters a state in which it waits for the reception of the first signal without receiving a sensor signal during the waiting time Twait described later. In Step S11, the controller 33 sends a gate signal=0 to the switching element 31. In Step S12, when the first signal is not received from the sensor 32, the controller 33 waits until it receives a sensor signal from the sensor 32. In Step S12, when the controller 33 receives the first signal from the sensor 32, the process proceeds to Step S13. In Step S13, when a second signal is not received from the sensor 32, the controller 33 waits until it receives a sensor signal from the sensor 32. In Step S13, when the controller 33 receives the second signal from the sensor 32, the process proceeds to Step S14.

In Step S14, the controller 33 calculates the time difference ΔT12 between receiving the first signal and receiving the second signal. For example, when T1 is the time of receiving the first signal and T2 is the time of receiving the second signal, the time difference ΔT12 can be calculated using the following Equation (1).

ΔT12=T2−T1 (1)

The controller 33 predicts a time T′3 at which the third impulse noise will arrive using the calculated time difference ΔT12. The time T′3 can be calculated using the following Equation (2). Note that when predicting the time at which an impulse noise will arrive, a single quotation mark' is used to distinguish it from the actual time at which a sensor signal will be received.

T′3=T2+ΔT12 (2)

In Step S15, when the controller 33 has not received a new sensor signal from the sensor 32, the process proceeds to Step S16. In Step S16, when the time difference ΔT12 has not yet elapsed from a time T2, the process returns to Step S15. By repeating steps S15 and S16, the controller 33 monitors whether an impulse noise has arrived before the time difference ΔT12 has elapsed. In Step S16, when the time difference ΔT12 has elapsed from the time T2, the process proceeds to Step S17.

In Step S15, when a third signal is received from the sensor 32, it can be determined that the third impulse noise has arrived before the time difference ΔT12 has elapsed. In this case, the process returns to Step S14, and again in Step S14, the controller 33 calculates the time difference ΔT23 between receiving the second signal and receiving the third signal, as in the Equation (1). The controller 33 predicts a time T′4 at which the fourth impulse noise arrives using the calculated time difference ΔT23, as in the Equation (2) above.

Here, a general description will be provided for the case of repeating the operation of Step S14. First, in Step S14, when n is an integer greater than or equal to two, a time difference ΔT(n−1) (n) between receiving an (n−1)th signal and receiving an nth signal is calculated. Then, by adding the time difference ΔT(n−1) (n) to the time of receiving the nth signal, an arrival time T′(n+1) of an (n+1)th impulse noise is calculated.

Next, in Step S15, upon receiving a sensor signal from the sensor 32, the process returns to Step S14. Then, the controller 33 increments an integer to be substituted for n by one and calculates the time difference ΔT(n−1) (n) between receiving the (n−1)th signal and receiving the nth signal. The controller 33 predicts the time T′(n+1) at which a next (n+1)th impulse noise will arrive using the calculated time difference ΔT(n−1) (n).

As described above, when the next impulse noise arrives before the time T′(n+1) predicted in Step S14 as the time at which the (n+1)th impulse noise arrives, the controller 33 receives a sensor signal corresponding to the impulse noise in Step S15. In Step S14 again, the controller 33 increments an integer to be substituted for n by one and re-predicts the time T′(n+1) at which the (n+1)th impulse noise arrives using the time difference ΔT(n−1) (n) between receiving the (n−1)th signal and receiving the nth signal. Thereafter, each time returning to Step S14, the controller 33 repeats the same operation, incrementing an integer to be substituted for n by one per repetition.

By setting an appropriate length of the off time Toff in advance, it is possible to prevent the propagation of the (n+1)th impulse noise to the load 2 via the power line 4 as a propagation path even when the arrival of the (n+1)th impulse noise is delayed slightly more than the predicted time T(n+1). Therefore, even when the arrival of the (n+1)th impulse noise is delayed slightly, there is no need to re-predict the time T(n+1). For example, the off time Toff is preset and stored in the memory of the controller 33.

In Step S16, when the time T(n+1) has not yet elapsed, the process returns to Step S15. By repeating Steps S15 and S16, the controller 33 monitors whether an impulse noise has arrived before the time T′(n+1) has elapsed. In Step S16, when the time T′(n+1) has elapsed, the process proceeds to Step S17. In Step S17, the controller 33 sends a gate signal=1 to the switching element 31. When the switching element 31 has received the gate signal=1, it remains in the off state for the off time Toff. The load 2 is disconnected from the power line 4, through which the impulse noises are propagated, by the switching element 31 turning to the off state.

In Step S18, when the off time Toff has not yet elapsed from the time T′(n+1), which is a time at which the (n+1)th impulse noise is predicted to arrive, the controller 33 waits until the off time Toff has elapsed.

In Step S18, when the off time Toff has elapsed, the process proceeds to Step S19.

In Step S19, the controller 33 sends a gate signal=0 to the switching element 31.

In Step S20, when the controller 33 has not received a sensor signal from the sensor 32 before the off time Toff has elapsed from the time T(n+1), which is a time at which the (n+1)th impulse noise is predicted to arrive, the process proceeds to Step S21. In Step S20, when the controller 33 has received a sensor signal from the sensor 32 before the off time Toff has elapsed, it can be determined that the (n+1)th impulse noise has arrived at the predicted time. In this case, the process returns to Step S14.

In Step S21, when the controller 33 has not received a sensor signal from the sensor 32 before the waiting time Twait has elapsed after the off time Toff has elapsed, the process proceeds to Step S22. In Step S21, when the controller 33 has received a sensor signal from the sensor 32 before the waiting time Twait has elapsed after the off time Toff has elapsed, it can be determined that a new impulse noise has arrived before the waiting time Twait has elapsed. The new impulse noise is, for example, a delayed fifth impulse noise. In this case, the process returns to Step S14. By repeating Steps S21 and S22, the controller 33 monitors whether an impulse noise has arrived before the waiting time Twait has elapsed.

In Step S22, when the waiting time Twait has elapsed, the process proceeds to Step S23. In Step S23, the controller 33 enters the steady state and completes the operation for noise removal for one burst consisting of the periodic impulse noises.

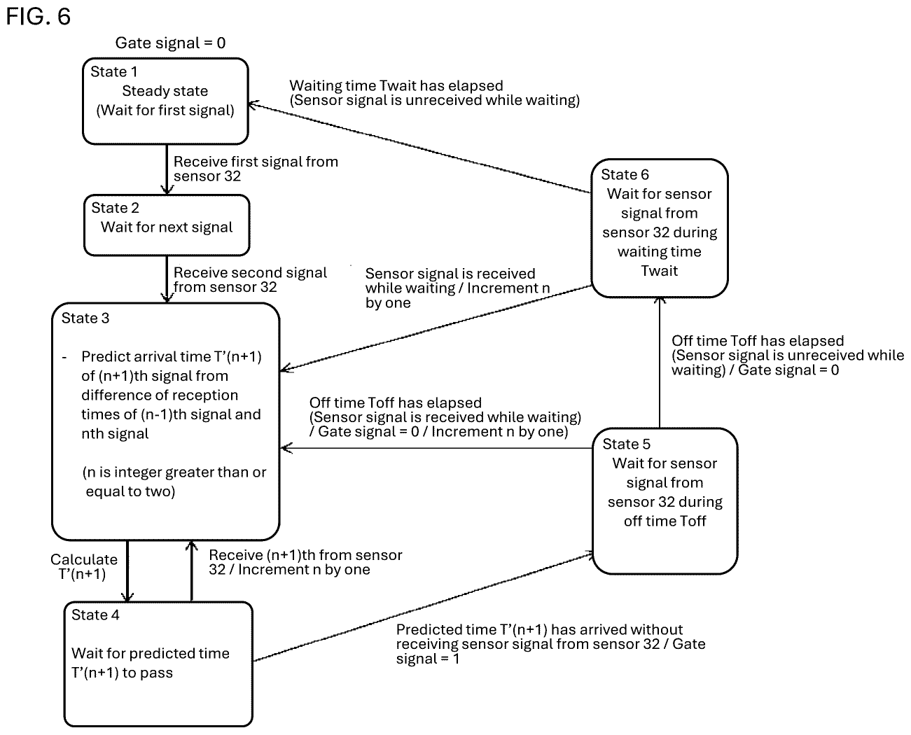

Next, state transitions of the controller 33 will be described. FIG. 6 is a state transition diagram of the controller 33. The state transition diagram is a diagram that describes a plurality of states of the controller 33 in squares, represents the state transitions with arrows, and puts information about triggers for the state transitions near the arrows.

In State 1 of FIG. 6, the controller 33 is in the steady state. When the controller 33 enters the steady state, it sends a gate signal=0 to the switching element 31. In the steady state, the controller 33 waits for a sensor signal from the sensor 32. When the controller 33 receives the first signal from the sensor 32, it transitions to State 2. At this time, for example, the controller 33 records the time T1 at which the first signal is received in the memory. In State 2 of FIG. 6, the controller 33 enters a state of waiting for the second signal. When the controller 33 receives the second signal from the sensor 32, it transitions to State 3.

In State 3, when the first signal and the second signal are received from the sensor 32, the controller 33 calculates the time difference ΔT12 between receiving the first signal and receiving the second signal. The controller 33 calculates the time T′3 by adding the time difference ΔT12 to the time T2 at which the second signal is received. The time T′3 refers to the predicted time at which the third impulse noise is predicted to arrive. Then, when the controller 33 has calculated the time T′3, it transitions to State 4.

In State 4, the controller 33 waits until the predicted time T′3. When the third signal is received from the sensor 32 before the predicted time T3, the controller 33 transitions to State 3.

When having transitioned from State 4 to State 3, the controller 33 calculates the time difference ΔT23 between receiving the second signal and receiving the third signal. The controller 33 calculates time T′4 by adding the time difference ΔT23 to the time T3 at which the third signal is received, and transitions back to State 4 again. The time T′4 refers to the predicted time at which the fourth impulse noise is predicted to arrive. In State 4 again, the controller 33 waits until the time T′4. When the controller 33 has received a sensor signal before the time T4, it transitions back to State 3 again.

A generalized description of the transitions involving State 3 and State 4 will be given. First, in State 3, the time difference ΔT(n−1) (n) is calculated, and by using this, the time T′(n+1) at which the (n+1)th impulse noise is predicted to arrive is calculated. Note that n is an integer greater than or equal to two. After transition to State 4, when a sensor signal is received before the predicted arrival time T′(n+1), the controller 33 transitions to State 3. Then, the controller 33 increments an integer to be substituted for n by one and calculates the time difference ΔT(n−1) (n) between receiving the (n−1)th signal and receiving the nth signal. The controller 33 recalculates the time T′(n+1), which is the time at which the (n+1)th impulse noise will arrive, by adding the time difference ΔT(n−1) (n) to the time T(n). Thereafter, each time the controller 33 transitions to State 3, it repeats the same operation and increments an integer to be substituted for n by one per repetition. In the case where the controller 33 has not received a sensor signal from the sensor 32 while waiting until the time T′(n+1), and when the time T′(n+1) has arrived, it outputs a gate signal=1 and transitions to State 5. The switching element 31 turns to the off state by receiving the gate signal=1. The operations when transitioning from State 5 to State 3 and from State 6 to State 3 are the same as those when transitioning from State 4 to State 3.

In State 5, the controller 33 waits for a sensor signal from the sensor 32 from the time T(n+1) at which the (n+1)th impulse noise is predicted to arrive until the off time Toff has elapsed.

When the sensor signal is received before the off time Toff has elapsed from the time T′(n+1), the controller 33 outputs a gate signal=0 after the off time Toff has elapsed and transitions to State 3. In State 3, the controller 33 increments an integer to be substituted for n by one to calculate the time difference ΔT(n−1) (n) between receiving the (n−1)th signal and receiving the nth signal, and then uses this result to calculate the time T(n+1) at which the next (n+1)th signal is further to arrive.

When the sensor signal is not received before the off time Toff has elapsed from the time T(n+1), the controller 33 outputs a gate signal=0 after the off time Toff has elapsed and transitions to State 6.

In State 6, the controller 33 waits for the sensor signal to be received further until the waiting time Twait has elapsed after the off time Toff elapsed. When the sensor signal is received before the waiting time Twait has elapsed, the controller 33 transitions to State 3. In State 3, the controller 33 increments an integer to be substituted for n by one and predicts the time T′(n+1) at which the (n+1)th signal is to arrive from the difference in the reception times between the (n−1)th signal and the nth signal. When the sensor signal is not received during the waiting time Twait, the controller 33 transitions to State 1 and returns to the steady state. The operation of the controller 33 in State 1 is the same as described above.

The noise filter 3 according to Embodiment 1 includes the sensor 32 and the controller 33. The sensor 32 detects the periodic impulse noises applied to the power line 4 to send the sensor signals to the controller 33. When the time equivalent to the time from detecting the first impulse noise to detecting the second impulse noise has elapsed after detecting the second impulse noise, the controller 33 turns off the switching element 31. Thus, the power source 1 and the load 2 are electrically disconnected in synchronization with the arrivals of the impulse noises. Therefore, the noise filter 3 according to Embodiment 1 can prevent the impulse noises from entering the load 2 without hindering the continuous operation of the load 2.

Although Embodiment 1 describes the case in which the power line 4 consists of two wires, it is also possible for the power line 4 to consist of three or more wires. It is sufficient to provide one switching element 31 for each wire of the power line 4. In this case, therefore, it is only necessary to prepare a number of the switching elements 31 corresponding to the number of wires forming the power line 4.

In Embodiment 1, the sensor 32 is described as being connected to the power source wire 41 and the power source wire 42. However, the sensor 32 may be located anywhere as long as it can detect the impulse noises applied to the power line 4. For example, the sensor 32 may be arranged to be connected in series with a capacitor having the function of removing the impulse noises. An example of such a capacitor is a Y-capacitor connected between the power line and ground.

As a modified example, the noise filter 3 may be provided with a power supply circuit 5 that supplies power to the load 2 when the load 2 is electrically disconnected from the power source 1. Here, it is assumed that the load 2 is, for example, a circuit used in precision equipment that cannot operate if electrically disconnected for even a few nanoseconds. In this case, the load 2 operates at a normal mode voltage. Even within the off time Toff, if the load 2 is electrically disconnected from the power source 1, that is, if the normal mode voltage applied to the load 2 falls below a certain value, the load will no longer be able to continue operating. Here, the normal mode voltage refers to the voltage between the first power source wire 41 and the second power source wire 42.

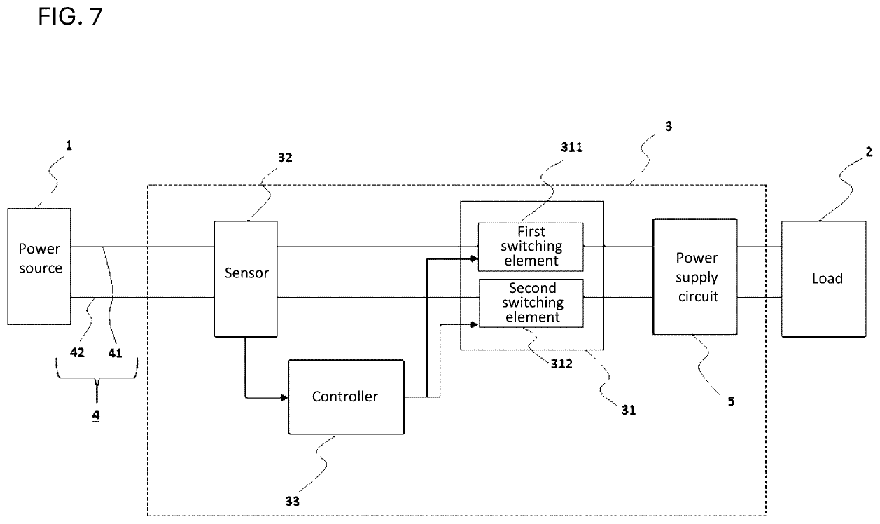

FIG. 7 is a configuration diagram of a noise filter according to the modified example of Embodiment 1. As shown in FIG. 7, the power supply circuit 5 is provided on the power line 4 between the switching element 31 and the load 2. When the switching element 31 is in the off state, the power supply circuit 5 supplies power to the load 2. The power supply circuit 5 is, for example, a capacitor. Any number is acceptable, or there is no limit for the number of capacitors that can be used as the power supply circuit 5. A capacitor provided for transient power-failure protection and current smoothing may be used as the power supply circuit 5.

When using a capacitor as the power supply circuit 5, a voltage drop occurs in the power supplied to the load 2, depending on a capacitance value of the capacitor and the power consumption of the load 2. Therefore, the capacitance value of the capacitor required to continue the operation of the load 2 is calculated from the power consumption of the load 2 and the length of the off time Toff during which the switching element 31 is in the off state.

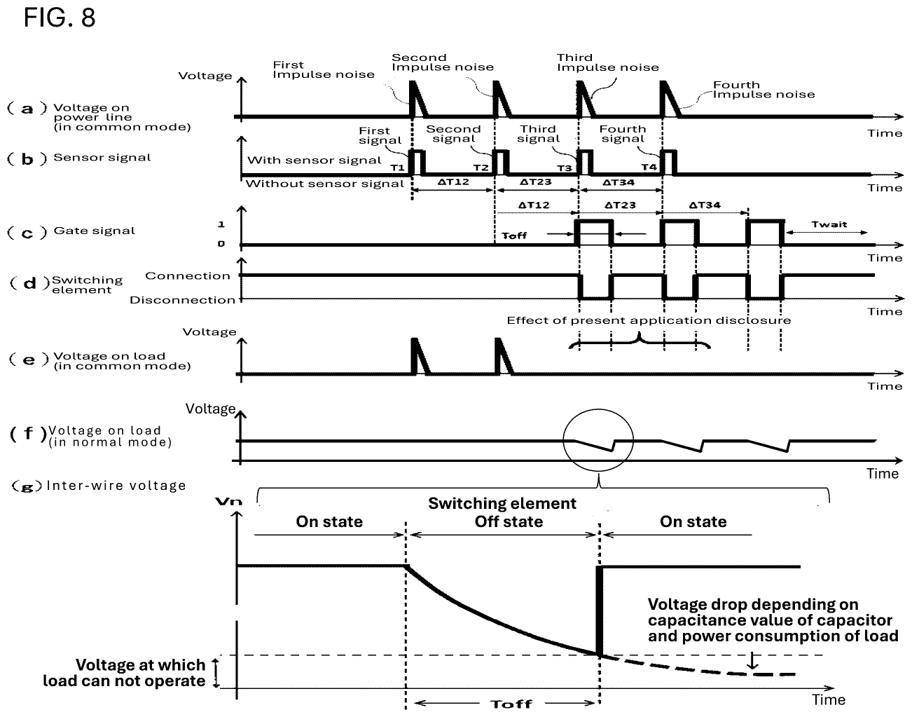

FIG. 8 is a schematic diagram showing the operation of the components of the noise filter 3, the voltage changes on the power line and the load, and the relationship between the off time Toff of the switching element 31 and an inter-wire voltage Vn, which is the voltage between the first power source wire 41 and the second power source wire 42, after the application of the noise filter 3. (a) to (e) in the upper part of FIG. 8 are the same as (a) to (e) in FIG. 4. FIG. 8(f) shows the change in the normal mode voltage on the load 2 after the application of the noise filter 3 according to the modified example. During the time in which the switching element 31 performs the electrical connection and disconnection between the power source 1 and the load 2, the normal mode voltage changes.

When the switching element 31 is turned to the off state, the power supply to the load 2 is cut off from the power source 1. Therefore, power is supplied from the capacitor used as the power supply circuit 5 to the load 2. In this case, as shown in FIG. 8(g), the inter-wire voltage Vn decreases over time in accordance with the discharge of the capacitor. Therefore, in order to continue the operation of load 2, the capacitor with sufficient capacity should be selected by calculation based on the power consumption of load 2 and the length of the off time Toff during which the switching element 31 remains in the off state.

When it is assumed that the power source 1 is located upstream and the load 2 is located downstream, it is sufficient for the components to be electrically connected in the following order from the upstream: the power source 1, the sensor 32, the controller 33, the switching element 31, the power supply circuit 5, and the load 2. It is also possible to place another circuit and element, such as a diode bridge and a DC-DC converter, another filter, or an input/output protection circuit, between the circuits and elements.

According to the modified example, the noise filter 3 of the present application includes the power supply circuit 5 that supplies power to the load 2 when the load 2 is electrically disconnected from the power source 1, so that even when the load 2 is a circuit to be installed in precision equipment that cannot operate when it is electrically disconnected for even a few nanoseconds, the load 2 can be continuously operated.

### Embodiment 2

In Embodiment 1, the case is described in which one switching element 31 is required for each wire of the power line 4. In the present embodiment, the case will be described in which the power line 4 has three or more wires and a diode bridge 6 is provided on the power line 4 between the power source 1 and the switching element 31. By placing the switching element 31 downstream of the diode bridge 6, it is possible to realize the configuration with only two switching elements even when the power line 4 consists of three or more wires. A noise filter 3 according to Embodiment 2 has most of the parts in common with the noise filter 3 according to Embodiment 1 or its modifications. Therefore, the following description shall focus on the differences from the noise filter 3 according to Embodiment 1 or its modifications and omit, as appropriate, descriptions of the common configurations, etc. shared with the noise filter 3 according to Embodiment 1 or its modifications.

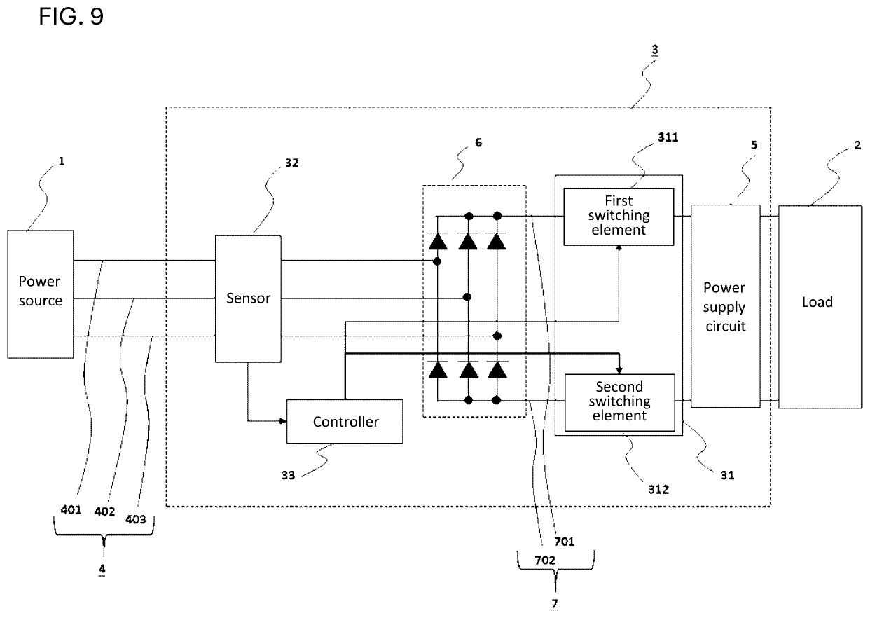

FIG. 9 shows a configuration diagram of the noise filter 3 according to Embodiment 2. In Embodiment 2, an example will be described for the case in which the power line 4 is for three-phase AC and the current flowing through the power line 4 is rectified by the diode bridge 6. The power line 4 consists of a first power source wire 401, a second power source wire 402, and a third power source wire 403, which are located closer to the power source 1 than the diode bridge 6. A power line 7, which is located closer to the load 2 than the diode bridge 6, consists of a first power source wire 701 and a second power source wire 702. The first power source wire 401, the second power source wire 402, and the third the power source wire 403 electrically connect the power source 1 and the diode bridge 6. The first power source wire 701 and the second power source wire 702 electrically connect the diode bridge 6 and the load 2. From here on, when it is not necessary to describe the first power source wire 701 and the second power source wire 702 separately, they will simply be referred to as the power line 7. The diode bridge 6 rectifies the three-phase AC supplied from the power source 1 into DC and outputs it. As a result, the diode bridge 6 receives three-wire inputs and provides them as two-wire outputs.

The configuration described in Embodiment 2 is the same as that of Embodiment 1, except that the power line 4 is for the three-phase AC and the diode bridge 6 is provided. That is, the configuration is the same as that of Embodiment 1 in that the configuration includes: the power source 1 which supplies power to the load 2; the load 2 which is supplied with power from the power source 1 via the power line 4 and is driven by the supplied power; and the noise filter 3 which is provided on the power line 4 to protect the load 2 from the impulse noises.

The configuration of the noise filter 3, which includes the switching element 31, the sensor 32, and the controller 33, is the same as that of Embodiment 1. The configuration of the switching element 31 which includes the first switching element 311 and the second switching element 312 is the same as that of Embodiment 1. As shown in FIG. 9, the first switching element 311 is provided on the first power source wire 701. The second switching element 312 is provided on the second power source wire 702.

Next, the operation of the noise filter 3 will be described. The sensor 32 detects an impulse noise propagating through the first power source wire 401, the second power source wire 402, and the third the power source wire 403 and sends a sensor signal to the controller 33. The controller 33 controls the on/off operation of the switching element 31 when receiving the sensor signal from the sensor 32. The operation performed by the controller 33 is the same as in Embodiment 1. The switching element 31 prevents the impulse noises from propagating to the load 2 by performing the on/off operation.

According to Embodiment 2, the diode bridge 6 is provided to rectify the three-phase AC into DC and output it, so that the three-wire inputs from the power line 4 are to be outputted as the two-wire outputs from the power line 7. Therefore, it is possible to configure the noise filter 3 with the switching elements 31 whose number is equal to the number of the wires of the power line 7, which is less than the number of the wires of the power line 4.

Note that, in Embodiment 2, the example of using the noise filter 3 with a three-phase 3-wire power source is described, the use is not limited to that. Even when used with a three-phase 4-wire power source, it is possible to build a noise filter with a smaller number of switching elements than the number of power source wires.

### DESCRIPTION OF SYMBOLS

1 . . . power source,
2 . . . load,
3 . . . noise filter,
4 . . . power line,
5 . . . power supply circuit,
6 . . . diode bridge,
7 . . . power line,
31 . . . switching element,
32 . . . sensor,
33 . . . controller,
41 . . . first power source wire,
42 . . . second power source wire,
311 . . . first switching element,
312 . . . second switching element,
401 . . . first power source wire,
402 . . . second power source wire,
403 . . . third power source wire,
701 . . . first power source wire,
702 . . . second power source wire

1. A noise filter comprising:
a switching element that is provided on a power line electrically connecting a power source and a load and switches the electrical connection and disconnection between the power source and the load by an on/off operation;
a sensor that detects periodic impulse noises applied to the power line; and
controlling circuitry that turns off the switching element when a time equivalent to a time from detecting a first impulse noise to detecting a second impulse noise has elapsed from detecting the second impulse noise.

2. The noise filter according to claim 1, further comprising a power supply circuit that is provided on the power line between the switching element and the load and supplies power to the load when the switching element is off.

3. The noise filter according to claim 1, wherein the sensor detects the second impulse noise that follows the first impulse noise.

4. The noise filter according to claim 1, wherein the switching element is a switching diode.

5. The noise filter according to claim 1, wherein the sensor is a voltage sensor or a current sensor.

6. The noise filter according to claim 2, wherein the power supply circuit is a capacitor.

7. The noise filter according to claim 1, wherein
when the sensor detects the first impulse noise, it sends a first signal corresponding to the first impulse noise to the controlling circuitry, and when the sensor detects the second impulse noise, it sends a second signal corresponding to the second impulse noise to the controlling circuitry, and
the controlling circuitry performs control to turn off the switching element at a time when a time difference between receiving the first signal and receiving the second signal has elapsed from the time of receiving the second signal.

8. The noise filter according to claim 1, further comprising a diode bridge that is provided on the power line between the power source and the switching element and rectifies three-phase AC supplied from the power source to DC to output the DC.

9. A noise removal method comprising:
detecting periodic impulse noises applied to a power line electrically connecting a power source and a load;
delivering a first signal corresponding to a first impulse noise for control when the first impulse noise is detected;
delivering a second signal corresponding to a second impulse noise for control when the second impulse noise is detected;
calculating a time difference between receiving the first signal and receiving the second signal;
determining whether the time difference has elapsed from receiving the second signal; and
performing control to turn off a switching element that switches the electrical connection and disconnection between the power source and the load by an on/off operation when the time difference has elapsed from the time of receiving the second signal.
